(19) United States
(12) Patent Application Publication
(10) Pub. No.: US 2025/0347574 A1
(43) Pub. Date: Nov. 13, 2025

(54) METHODS AND APPARATUS FOR REACTION SPACE PRESSURE MEASUREMENT

(71) Applicant: ASM IP Holding B.V., Almere (NL)

(72) Inventors: Aadil Vora, Tempe, AZ (US); Xiangdong Qin, Chandler, AZ (US); Michael Schmotzer, Chandler, AZ (US); Leonard Rodriguez, Phoenix, AZ (US)

(21) Appl. No.: 19/200,839

(22) Filed: May 7, 2025

Related U.S. Application Data
(60) Provisional application No. 63/645,641, filed on May 10, 2024.

(51) Int. Cl. G01L 19/00; C23C 16/455

(52) U.S. Cl. CPC G01L 19/0015; C23C 16/45557; C23C 16/45561

(57) ABSTRACT

Various embodiments of the present technology may provide a system having a reactor with a reaction space and a pressure monitoring system configured to measure the pressure inside the reaction space. The pressure monitoring system may include two or more pressure sensors, wherein each pressure sensor can be isolated with two valves, one valve arranged upstream from the pressure sensor and another valve arranged downstream from the pressure sensor.

### CROSS-REFERENCE TO RELATED APPLICATIONS

This application is a nonprovisional of, and claims priority to and the benefit of, U.S. Provisional Patent Application No. 63/645,641, filed May 10, 2024 and entitled “METHODS AND APPARATUS FOR REACTION SPACE PRESSURE MEASUREMENT,” which is hereby incorporated by reference herein.

### FIELD OF INVENTION

The present disclosure generally relates to a method and apparatus for reaction space pressure measurement. More particularly, the present disclosure relates to a reactor having multiple pressure sensors coupled to the reaction space, wherein the pressure sensors can also be isolated.

### BACKGROUND OF THE TECHNOLOGY

Conventional reaction chambers do not have a way to directly measure the pressure within the reaction space where the wafer sits during deposition. It is undesired to install a pressure sensor within the reaction space due to film that builds up on the pressure sensor, which eventually causes the pressure sensor to fail or give mis-readings.

### SUMMARY OF THE INVENTION

Various embodiments of the present technology may provide a system having a reactor with a reaction space and a pressure monitoring system configured to measure the pressure inside the reaction space. The pressure monitoring system may include two or more pressure sensors, wherein each pressure sensor can be isolated with two valves, one valve arranged upstream from the pressure sensor and another valve arranged downstream from the pressure sensor.

According to one aspect, an apparatus comprises: a gas distribution system comprising an inlet coupled to a vessel, the vessel configured to contain a precursor; a reaction chamber disposed below the gas distribution system and comprising a susceptor and a reaction space defined by the susceptor and the gas distribution system; and a pressure monitor system comprising: a first valve coupled to and in fluid communication with the reaction space; a second valve coupled in series with the first valve at a first junction; a third valve coupled to and in fluid communication with the reaction space; a fourth valve coupled in series with the third valve at a second junction; a first pressure sensor coupled to the first junction; and a second pressure sensor coupled to the second junction.

In one embodiment of the above apparatus, the first, second, third, and fourth valves are disposed outside of the reaction chamber and gas distribution system.

In one embodiment of the above apparatus, the first and second pressure sensors are disposed outside of the reaction chamber and gas distribution system.

In one embodiment of the above apparatus, the pressure monitor system is coupled to an inert gas source.

In one embodiment, the above apparatus further comprises a controller configured to operate each of the first, second, third, and fourth valves independently from each other.

In one embodiment of the above apparatus, the first and second pressure sensors comprise a pressure transducer.

In one embodiment of the above apparatus, the first and third valves are coupled in direct fluid communication with the reaction space.

In one embodiment, the above apparatus further comprises an inert gas source coupled to the pressure monitor system.

In another aspect, an apparatus comprises: a gas distribution system comprising an inlet coupled to a vessel, the vessel configured to contain a precursor; a reaction chamber disposed below the gas distribution system and comprising a susceptor and a reaction space defined by the susceptor and the gas distribution system; and a pressure monitor system disposed outside of the reaction chamber and distribution system, and comprising: a first plurality of valves coupled to and in fluid communication with the reaction space; a second plurality of valves coupled to and in fluid communication with the reaction space, wherein the second plurality of valves are separated from the first plurality of valves by the reaction space; and a plurality of pressure sensors, wherein at least one pressure sensor is coupled to the first plurality of valves and at least one pressure sensor is coupled to the second plurality of valves.

In one embodiment of the above apparatus, the first plurality of valves comprises: a first valve coupled directly to and in fluid communication with the reaction space; and a second valve coupled in series with the first valve at a first junction.

In one embodiment of the above apparatus, the second plurality of valves comprises: a third valve coupled directly to and in fluid communication with the reaction space; and a fourth valve coupled in series with the third valve at a second junction.

In one embodiment of the above apparatus, the plurality of pressure sensors comprises: a first pressure sensor coupled to the first junction; and a second pressure sensor coupled to the second junction.

In one embodiment of the above apparatus, the pressure monitor system is coupled to an inert gas source.

In one embodiment of the above apparatus, the pressure monitor system is in direct fluid communication with the reaction space.

In yet another aspect, a method for monitoring pressuring in a reaction space comprises:
during a first pulsing period: opening a first valve that is coupled to the reaction space; closing a second valve, a third valve, and a fourth valve, wherein each are coupled to the reaction space; pulsing a first precursor into the reaction space via an inlet plenum; measuring a pressure in the reaction space with a first pressure sensor that is coupled between the first and second valves; and during a first purging period, purging the first valve with an inert gas that is coupled to the first valve; during a second pulsing period: opening the third valve; closing the first, second, and fourth valves; pulsing a second precursor into the reaction space via the inlet plenum; and measuring a pressure in the reaction space with a second pressure sensor that is coupled between the third and fourth valves; and during a second purging period, purging the third valve with the inert gas, wherein the inert gas is coupled to the third valve.

In one embodiment of the above method, purging the first valve comprises opening the second valve, wherein the second valve is coupled in series with the first valve.

In one embodiment of the above method, purging the third valve comprises opening the fourth valve, wherein the fourth valve is coupled in series with the third valve.

In one embodiment of the above method, the first purging period further comprises flowing an inert gas through the inlet plenum and into the reaction space after the first pulsing period.

In one embodiment of the above method, the second purging period further comprises flowing an inert gas through the inlet plenum and into the reaction space after the second pulsing period.

In one embodiment of the above method, the first, second, third and fourth valves and the first and second pressure sensors are disposed outside the reaction space.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology; and

FIG. 2 is a method for operating the system in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, and susceptors.

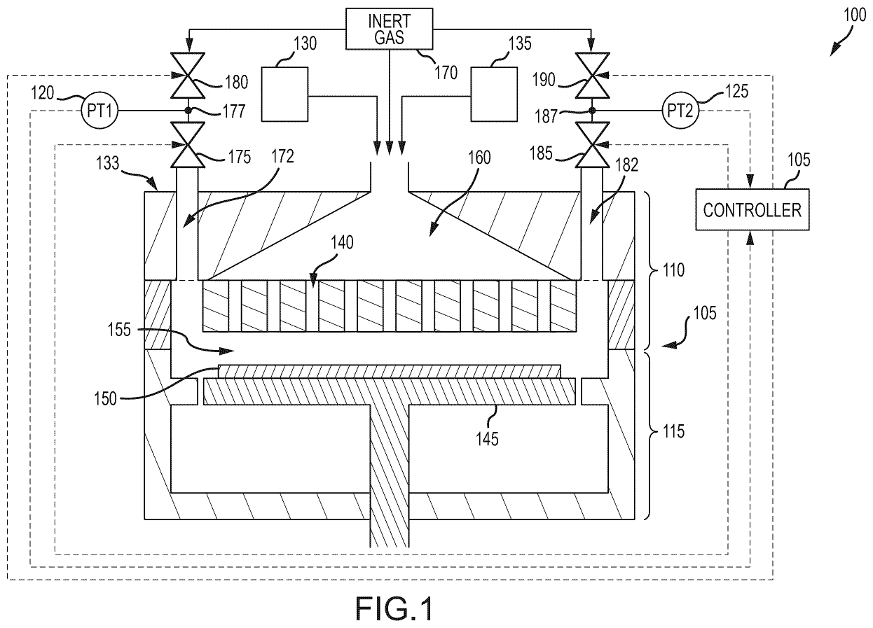

Referring to FIG. 1, an exemplary system 100 may comprise a reactor 105 configured to perform processing on an object to be processed, such as a substrate 150 (e.g., a wafer). For example, the reactor 105 may be configured to perform heating, deposition, etching, polishing, ion implantation, and/or other processing on the object to be processed. In some embodiments, the reactor 105 may be configured to perform a movement function, a vacuum sealing function, an exhaust function. In some embodiments, the reactor 105 may perform and atomic layer deposition (ALD) process or a chemical vapor deposition (CVD) process.

In an exemplary embodiment, the reactor 105 may comprise a reaction chamber 115 comprising a reaction space 155 above and/or around the substrate 150. The reaction chamber 115 may comprise sidewalls and a bottom coupled to the sidewalls.

In various embodiments, the system 100 may further comprise a substrate mounting unit disposed within the reaction chamber 115 of the reactor 105. The substrate mounting unit may comprise a susceptor 145 for supporting the substrate 150 and a heater (not shown) for heating the substrate 150 supported by the susceptor 145. The heater may be embedded within the susceptor 145. The substrate mounting unit may further comprise a pedestal to support the susceptor 145. For loading/unloading of the substrate, the substrate mounting unit may be configured to be vertically movable (up and down) by being connected to a driving unit (not shown). The susceptor 145 may be disposed in or adjacent the reaction space 155. For example, the susceptor 145 may be arranged to position the substrate 150 in the reaction space 155.

In various embodiments, the reactor 105 may further comprise a gas distribution system 110 for delivering a vapor into the reaction space 155. In an exemplary embodiment, the gas distribution system 110 is arranged above the susceptor 145 and reaction chamber 115.

In various embodiments, the gas distribution system 110 may be arranged adjacent to the reaction chamber 115. For example, the gas distribution system 110 may be arranged on the sidewalls of the reaction chamber 115, opposite the bottom of the reaction chamber 115. In some embodiments, the gas distribution system 110 may be fastened to the sidewalls, however, in other cases, the gas distribution system 110 may merely rest on the sidewalls of the reaction chamber 115. In various embodiments, the gas distribution system 110 together with the reaction chamber 115 sidewalls form an enclosed space, including the reaction space 155. The reaction space 155 may be defined by the volume between the susceptor 145 surface that supports the wafer 150 and a downward-facing surface of the gas distribution system 110.

In various embodiments, the gas distribution system 110 may comprise an inlet plenum 160 configured to receive vapor from at least one of a first vessel 130, a second vessel 135 or an inert gas source 170. The gas distribution system 110 may comprise a plurality of inlet through-holes 140 that extend through a portion of the gas distribution system 110. The plurality of inlet through-holes 140 may be arranged within a central region (also referred to as a showerhead region) directly above the substrate 150. The inlet plenum 160 may be in fluid communication with the plurality of inlet through-holes 140. For example, the vapor that flows into the inlet plenum 140 may continue to flow through the plurality of through-holes 140. The plurality of inlet through-holes 140 may also be in fluid communication with the reaction space 155. For example, the vapor may flow through the plurality of inlet through-holes 140 and into the reaction space 155.

In addition, the gas distribution system 110 may further comprise at least two outlet through-holes, for example, a first outlet 172 and a second outlet 182. The first and second outlets 172, 182 may extend through the gas distribution system 110 such that the outlets 172, 182 provide a direct flow path from the reaction space 155 to the atmosphere outside the reactor 105. For example, each outlet 172, 182 may comprise a first end in fluid communication with the reaction space 155 and a second end that terminates at an exterior surface of the reactor 105. In an exemplary embodiment, the second ends of the outlets 172, 182 terminate at an exterior surface 133 of the gas distribution system 110. In other embodiments, the second end may terminate at an exterior surface of the reaction chamber 115 or the like.

In various embodiments, the first and second vessels 130, 135 may be configured to contain a chemical (i.e., a precursor). Each vessel 130, 135 may be configured to hold a solid, a liquid, or gas chemical, and may further be configured to transform the solid or liquid into a vapor. For example, the first vessel 130 may hold a first precursor and a the second vessel 135 may hold a second precursor that is different from the first precursor. Each vessel 130, 135 may be coupled to the gas distribution system 110. For example, the system 100 may further comprise various gas conduits and/or valves to flow the vapor from each vessel 130, 135 into the gas distribution system 110, and in particular, into the inlet plenum 160, through the through-holes and into the reaction space 155.

In various embodiments, the inert gas source 170 may provide an inert gas, such as argon or nitrogen, into various components of the system 100. For example, the inert gas source 170 may be coupled to the inlet plenum 160 to purge the inlet plenum 160, the through-holes 140, and the reaction space 155.

In various embodiments, the system 100 may further comprise a pressure monitoring system configured to measure the pressure in the reaction space 155. In an exemplary embodiment, the pressure monitoring system may be fluidly coupled to the first and second outlets 172, 182. The pressure monitoring system may comprise a plurality of valves, such as a first valve 175, a second valve 180, a third valve 185, and a fourth valve 190. Each of the valves may comprise an isolation valve, such as a solenoid valve, a piston valve, a diaphragm valve, or the like. The first valve 175 may be in direct fluid communication with the reaction space 155 via the first outlet 172, and the second valve 182 may be in direct fluid communication with the reaction space 155 via the second outlet 182. The second valve 180 may be coupled in series with the first valve 175 at a first junction 177. Similarly, the fourth valve 190 may be coupled in series with the third valve 185 at a second junction 187. The second and fourth valves 180, 190 may also be coupled to the inert gas source 170.

The pressure monitoring system may further comprise a plurality of pressure sensors, such as a first pressure sensor 120 and a second pressure sensor 125 configured to measure the pressure in the reaction space pressure sensor 130 may comprise any suitable pressure sensor, such as a pressure transducer, that measures the pressure and converts the measured pressure into an electrical signal, or the like. The first pressure sensor 120 may be coupled to the first and second valves 175, 180. For example, the first pressure sensor 120 may be coupled to the first junction 177. Similarly, the second pressure sensor 125 may be coupled to the third and fourth valves 185, 190, for example, to the second junction 187.

In various embodiments, the system 100 may further comprise a controller 105 configured to control operation of various components within the system such as the first, second, third, and fourth valves 175, 180, 185, 190. For example, the controller 105 may be electrically and/or commutatively coupled to the first, second, third, and fourth valves 175, 180, 185, 190 and may transmit a control signal to each one that indicates an operation mode (i.e., open or closed). The controller 105 may also receive information, data, or signals from other components, such as the first and second pressure sensors 120, 125.

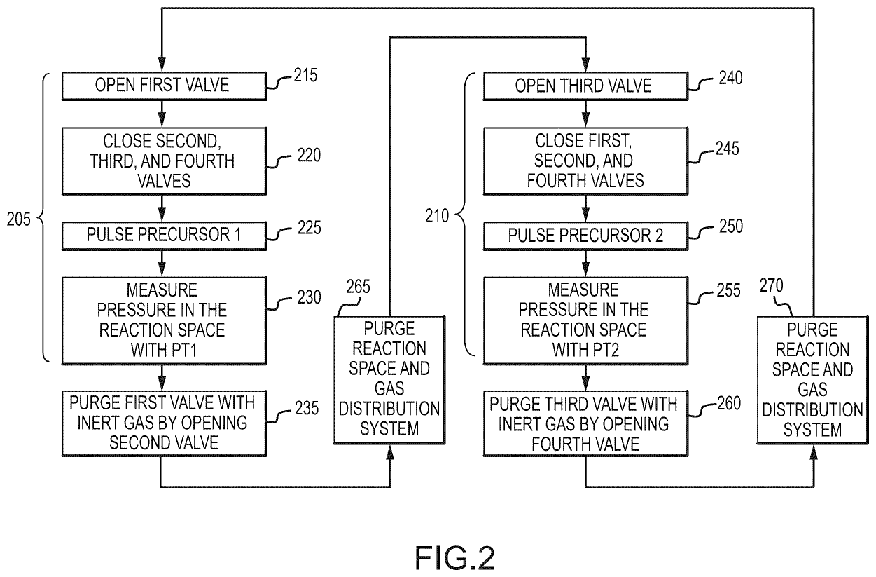

In operation, and referring to FIGS. 1 and 2, a method for operating the system 100 may comprise a first pulsing period 205 and a second pulsing period 210. The first pulsing period 205 may be followed by a first purging period, and the second pulsing period 210 may be followed by a second purging period.

In an exemplary embodiment, the first pulsing period 205 may comprise opening the first valve 175 (215) (via a signal from the controller 105) so that the first pressure sensor 120 is exposed to and is able to measure the pressure in the reaction space 155. The controller 105 may also send signals to close the second, third, and fourth valves 180, 185, 190 (220). Once the valves 175, 180, 185, 190 are set to the desired state, the controller 105 may enable a pulse of the first precursor into the reaction space 155 (225). The first pulsing period 205 may further comprise measuring the pressure in the reaction space 155 with the first pressure sensor 120 (230).

In various embodiments, the first purging period may comprise one or more purging steps. For example, the controller 105 may purge the first valve 175 by opening the second valve 180 and flowing the inert gas through the first and second valves 175, 180 (235). At the substantially the same time or after the first valve 175 is purged, the reaction space 155 and gas distribution system 110 may be purged by flowing the inert gas through the inlet plenum and into the reaction space 155 (265).

In an exemplary embodiment, the second pulsing period 210 may comprise opening the third valve 185 (240) (via a signal from the controller 105) so that the second pressure sensor 125 is exposed to and is able to measure the pressure in the reaction space 155. The controller 105 may also send signals to close the first, second, and fourth valves 175, 180, 190 (245). Once the valves 175, 180, 185, 190 are set to the desired state, the controller 105 may enable a pulse of the second precursor into the reaction space 155 (250). The second pulsing period 210 may further comprise measuring the pressure in the reaction space 155 with the second pressure sensor 125 (255).

In various embodiments, the second purging period may comprise one or more purging steps. For example, the controller 105 may purge the third valve 185 by opening the fourth valve 190 and flowing the inert gas through the third and fourth valves 185, 190 (260). At the substantially the same time or after the third valve 185 is purged, the reaction space 155 and gas distribution system 110 may be purged by flowing the inert gas through the inlet plenum and into the reaction space 155 (270).

In an alternative method, the first valve purging step (235) may be performed at substantially the same time as pulsing of the first precursor (220). Similarly, the third valve purging step (260) may be performed at substantially the same time as pulsing of the second precursor (250).

In various embodiments, the system 100 may utilize the measured pressures to adjust various conditions in the reaction space, such as temperature and/or flow rate, in order to maintain a desired pressure in the reaction space 155. For example, the temperature of the susceptor 150 may be adjusted, and/or the flow rate of the precursors into the reaction space 155 may be adjusted.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a gas distribution system comprising an inlet coupled to a vessel, the vessel configured to contain a precursor;
a reaction chamber disposed below the gas distribution system and comprising a susceptor and a reaction space defined by the susceptor and the gas distribution system; and
a pressure monitor system comprising:
a first valve coupled to and in fluid communication with the reaction space;
a second valve coupled in series with the first valve at a first junction;
a third valve coupled to and in fluid communication with the reaction space;
a fourth valve coupled in series with the third valve at a second junction;
a first pressure sensor coupled to the first junction; and
a second pressure sensor coupled to the second junction.

2. The apparatus according to claim 1, wherein the first, second, third, and fourth valves are disposed outside of the reaction chamber and gas distribution system.

3. The apparatus according to claim 1, wherein the first and second pressure sensors are disposed outside of the reaction chamber and gas distribution system.

4. The apparatus according to claim 1, wherein the pressure monitor system is coupled to an inert gas source.

5. The apparatus according to claim 1, further comprising a controller configured to operate each of the first, second, third, and fourth valves independently from each other.

6. The apparatus according to claim 1, wherein the first and second pressure sensors comprise a pressure transducer.

7. The apparatus according to claim 1, wherein the first and third valves are coupled in direct fluid communication with the reaction space.

8. The apparatus according to claim 1, further comprising an inert gas source coupled to the pressure monitor system.

9. An apparatus, comprising:
a gas distribution system comprising an inlet coupled to a vessel, the vessel configured to contain a precursor;
a reaction chamber disposed below the gas distribution system and comprising a susceptor and a reaction space defined by the susceptor and the gas distribution system; and
a pressure monitor system disposed outside of the reaction chamber and distribution system, and comprising:
a first plurality of valves coupled to and in fluid communication with the reaction space;
a second plurality of valves coupled to and in fluid communication with the reaction space, wherein the second plurality of valves are separated from the first plurality of valves by the reaction space; and
a plurality of pressure sensors, wherein at least one pressure sensor is coupled to the first plurality of valves and at least one pressure sensor is coupled to the second plurality of valves.

10. The apparatus according to claim 9, wherein the first plurality of valves comprises:
a first valve coupled directly to and in fluid communication with the reaction space; and
a second valve coupled in series with the first valve at a first junction.

11. The apparatus according to claim 10, wherein the second plurality of valves comprises:
a third valve coupled directly to and in fluid communication with the reaction space; and
a fourth valve coupled in series with the third valve at a second junction.

12. The apparatus according to claim 11, wherein the plurality of pressure sensors comprises:
a first pressure sensor coupled to the first junction; and
a second pressure sensor coupled to the second junction.

13. The apparatus according to claim 9, wherein the pressure monitor system is coupled to an inert gas source.

14. The apparatus according to claim 9, wherein the pressure monitor system is in direct fluid communication with the reaction space.

15. A method for monitoring pressuring in a reaction space, comprising:
during a first pulsing period:
opening a first valve that is coupled to the reaction space;
closing a second valve, a third valve, and a fourth valve, wherein each are coupled to the reaction space;
pulsing a first precursor into the reaction space via an inlet plenum;
measuring a pressure in the reaction space with a first pressure sensor that is coupled between the first and second valves; and
during a first purging period, purging the first valve with an inert gas that is coupled to the first valve;
during a second pulsing period:
opening the third valve;
closing the first, second, and fourth valves;
pulsing a second precursor into the reaction space via the inlet plenum; and
measuring a pressure in the reaction space with a second pressure sensor that is coupled between the third and fourth valves; and
during a second purging period, purging the third valve with the inert gas, wherein the inert gas is coupled to the third valve.

16. The method according to claim 15, wherein purging the first valve comprises opening the second valve, wherein the second valve is coupled in series with the first valve.

17. The method according to claim 15, wherein purging the third valve comprises opening the fourth valve, wherein the fourth valve is coupled in series with the third valve.

18. The method according to claim 15, wherein the first purging period further comprises flowing an inert gas through the inlet plenum and into the reaction space after the first pulsing period.

19. The method according to claim 15, wherein the second purging period further comprises flowing an inert gas through the inlet plenum and into the reaction space after the second pulsing period.

20. The method according to claim 15, wherein the first, second, third and fourth valves and the first and second pressure sensors are disposed outside the reaction space.
